(19) United States
(12) Patent Application Publication
(10) Pub. No.: US 2013/0118585 A1
(43) Pub. Date: May 16, 2013

(54) NANOCRYSTALLINE COPPER INDIUM DISELENIDE (CIS) AND INK-BASED ALLOYS ABSORBER LAYERS FOR SOLAR CELLS

(71) Applicants: Timothy James Anderson, Gainesville, FL (US); Chinho Park, Seoul (KR); Rangarajan Krishnan, Hillsboro, OR (US); Umme Farva, Sitapur (IN)

(72) Inventors: Timothy James Anderson, Gainesville, FL (US); Chinho Park, Seoul (KR); Rangarajan Krishnan, Hillsboro, OR (US); Umme Farva, Sitapur (IN)

(73) Assignee: UNIVERSITY OF FLORIDA RESEARCH FOUNDATION, INC., GAINESVILLE, FL (US)

(21) Appl. No.: 13/805,804

(22) PCT Filed: Jun. 22, 2011
(86) PCT No.: PCT/US2011/041349

§ 371 Date: Feb. 1, 2013

Related U.S. Application Data
(60) Provisional application No. 61/357,170, filed on Jun. 22, 2010.

(51) Int. Cl. H01L 31/18; H01L 31/032; H01L 31/0272

(52) U.S. Cl. CPC H01L 31/18; H01L 31/0272; H01L 31/0322; Y10S 977/773; Y10S 977/896; Y10S 977/824; B82Y 40/00
USPC 136/264; 423/508; 252/501.1; 438/95; 977/773; 977/896; 977/824

(57) ABSTRACT

Embodiments of the invention are to a copper indium diselenide (CIS) comprising nanoparticle where the nanoparticle includes a CIS phase and a second phase comprising a copper selenide. The CIS comprising nanoparticles are free of surfactants or binding agents, display a narrow size distribution and are 30 to 500 nm in cross section. In an embodiment of the invention, the CIS comprising nanoparticles are combined with a solvent to form an ink. In another embodiment of the invention, the ink can be used for screen or ink-jet printing a precursor layer that can be annealed to a CIS comprising absorber layer for a photovoltaic device.

### CROSS-REFERENCE TO RELATED APPLICATION

The present application claims the benefit of U.S. Provisional Application Ser. No. 61/357,170, filed Jun. 22, 2010, which is hereby incorporated by reference herein in its entirety, including any figures, tables, or drawings.

The subject invention was made with government support under the Department of Energy, Contract No. DE-FG36-08GO18069. The government has certain rights to this invention.

### BACKGROUND OF INVENTION

Recently, copper indium diselenide (CIS) and related chalcopyrite alloys have been intensively studied worldwide as a promising material system for thin film photovoltaics owing to their unique structural and optoelectronic properties. CIS and its alloys have tremendous potential to reduce the manufacturing costs of thin film solar cells relative to that for crystalline silicon-based solar cells. The technical challenge is to synthesize CIS based absorber layers at high throughput and yield while maintaining good cell performance. Various approaches that have been attempted for deposition of the material and synthesis of the CIS chalcopyrite layer include evaporation, sputtering, metal oxide reduction and selenization, selenization of intermetallics, electrodeposition, and nanoparticles synthesis.

Currently practiced techniques for depositing CIS absorber layers, including evaporation, sputtering, and selenization of intermetallics, are carried out at higher temperatures, which limits the substrate upon which it is deposited, and for extended periods of time, which decreases throughput and increases costs. Flexible substrates, such as polyimide, although attractive from the material properties and costs that would advance the solar cell market are not readily used with these techniques.

Alternative CIS deposition methods include electrodeposition and solution-based printing. As these processes require precise stoichiometric control, the solution-based printing using nanoparticles appears to be the better option for deposition. Nanoparticle-based absorber layer deposition and synthesis is attractive because a non-vacuum deposition process can be used and the method allows the use of flexible substrates. Solution processing of thin film solar cells involving nanocrystal inks is also attractive for the reduction of the fabrication cost per watt for photovoltaic modules. To achieve a high quality absorber layer, and hence a high quality photovoltaic cell, the texture, grain size and point defect chemistry of the CIS based absorber layer is critical. A key factor for a high quality layer is the nanoparticle synthesis.

Various size, shape and structure of various inorganic nanocrystals have been investigated with respect to formulating inks that are suitable for photovoltaic cell applications. The shape, size and structure of the synthesized nanomaterials correlate strongly with the physical, chemical and optoelectronic properties achieved. Various synthesis routes have been taken in the attempt to optimize nanostructure growth for thin film solar cell applications. Methods for the synthesis of nanoparticle include hot-injection and a solvothermal route. These methods of nanoparticle synthesis process often suffer from the ease of scalable or control of the morphology and stoichiometry. For instance, hot-injection requires a surfactant to control the size and shape of the nanocrystals and a binding material must be added to the solution. This requires higher temperatures for annealing and removal of the binding material from the substrate. These higher temperatures preclude the use of flexible polymeric substrates. For these reasons, a new process for manufacturing nanocrystals is required where binding materials can be avoided and relatively low temperature layer formation can be carried out.

### BRIEF SUMMARY

Embodiments of the invention are directed to CIS comprising nanoparticle containing: Cu where some of the Cu can be replaced with Au or Ag; In, Al, Zn, Sn, Ga, or any combination thereof; and Se, S, Te or any combination thereof and have a secondary phase of copper selenide, or any other compound that exhibits peritectic decomposition, with no surfactant or binding agent. The secondary phase is copper rich comprising CuSe, CuSe₂, Cu₃Se₂, or any combination thereof. The CIS comprising nanoparticle can have a cubic (spharelite) or tetragonal (chalcopyrite) CIS crystal lattice. The cation lattice of the CIS can have In substituted by Al, Zn, Sn, or Ga and the Cu can be substituted with Au or Ag. The anion lattice can have Se substituted with S or Te. The CIS crystal lattice can form a solid solution that comprises Al, Zn, Au, Sn, Ga, Ag or any combination thereof. The CIS crystal lattice can form a solid solution comprising S or Te or any combination thereof. The CIS comprising nanoparticle can be 10 to 500 nm in cross section and the distribution of cross sections can be narrow.

Another embodiment of the invention is directed to a method to prepare the CIS comprising nanoparticles where a copper halide or its equivalent in a first solution, an indium halide or its equivalent in a second solution, and selenium, sulfur, or tellurium in a third solution are combined followed by heating to a temperature up to 150° C. to form a precipitate. The resulting CIS comprising nanoparticles can be washed. The solvents used for the first solution and second solution can be an alcohol. The solvent for the third solution can be an amine or a diamine. The solvents can be selected to allow the heat to be controlled by the temperature where the solvent mixture refluxes at a temperature that can be as low as about 90° C. or even less. A precipitate of the CIS comprising nanoparticle can be washed with a volatile alcohol such as methanol, which easily allows the washed precipitate to be dried.

In another embodiment of the invention the CIS comprising nanoparticles are combined with a solvent or mixture of solvents to form an ink. Solvents that can be used include alcohols and sulfoxides. The CIS comprising nanoparticles can be a blend of different CIS comprising nanoparticles of various sizes, shapes or elemental composition, the proportions of which can be easily made with dried CIS comprising nanoparticles.

Embodiments of the invention are directed to a method of preparing a CIS comprising absorber layer by forming a layer of the ink on a surface and removing the solvent from the ink to form a precursor layer followed by annealing the precursor layer under an overgas of selenium, sulfur or tellurium to form the CIS comprising absorber layer. The deposition of the ink layer can be carried out by spray coating, drop casting, screen printing, or inkjet printing. Annealing can be conducted at a maximum temperature of about 380° C., for example about 280° C. Upon annealing a CIS comprising absorber layer is formed that comprises CuInSe₂ where the layer has a microstructure that has lamellar grains alone or in addition to columnar grains, according to an embodiment of the invention.

Another embodiment of the invention is directed to a photovoltaic device having the novel CIS comprising absorber layer. The relatively mild method of preparing the absorber layer permits the device to be constructed on a metallic or polymeric substrate, such as stainless steel or a polyimide.

### BRIEF DESCRIPTION OF DRAWINGS

FIG. 1 is an illustrative scheme connecting a CIS comprising nanoparticles to an ink prepared from the CIS comprising nanoparticles used for a method involving ink deposition and annealing of the ink deposited precursor layer to form a CIS comprising absorber layer for a photovoltaic device in accordance with embodiments of the subject invention.

FIG. 2 are TEM images of CIS comprising nanoparticles from different Cu-precursors: (a) CuCl and (b) Cu(OC(O)CH₃)₂ according to embodiments of the invention.

FIG. 3 is a plot of XRD scans for 10° C. increments in temperature for Experimental sample UF5 according to an embodiment of the invention.

FIG. 4 is a plot of XRD scans for 10° C. increments in temperature for Experimental sample UF5′ according to an embodiment of the invention.

FIG. 5 is a plot of XRD scans for 10° C. increments in temperature for Experimental sample UF9 according to an embodiment of the invention.

### DETAILED DISCLOSURE

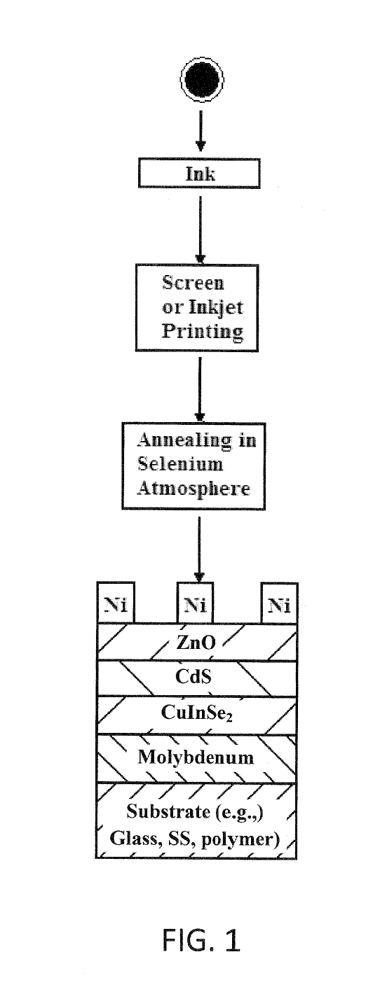

Embodiments of the invention are directed to a copper indium diselenide (CIS) comprising absorber layer from CIS comprising nanoparticles having a secondary phase comprising a compound that decomposes to a liquid, for example a copper selenide, for example CuSe₂, CuSe, and or Cu₃Se₂ and a photovoltaic cell comprising the CIS comprising absorber layer. FIG. 1 give a schematic representation of CIS comprising nanoparticles, an Ink prepared from the CIS comprising nanoparticles, method steps to deposit the ink as a precursor layer and conversion of the precursor layer to a CIS comprising absorber layer for a photovoltaic device as exemplified at the bottom of the scheme. The CIS comprising nanoparticles according to an embodiment of the invention are copper selenide rich, which is achieved by growing the nanoparticles under conditions rich in copper ion and selenium. The copper selenide rich conditions results in the formation of the secondary phase during the process of forming the CIS nanoparticles and results in a superior CIS comprising absorber layer. The copper selenide rich secondary phase can produce grain structure of the CIS comprising absorber layer by columnar growth or lamellar growth by a liquid assisted growth mechanism, where a eutectic mixture tends to produce lamellar or rod-like structure growth. The growth of the grain can be readily controlled by the composition of the CIS comprising nanoparticles and the conditions of the absorber layers growth.

Embodiments of the invention are directed to a method of preparing the CIS comprising nanoparticles. The CIS comprising nanoparticles can be from about 10 to about 500 nm on average in size, for example about 30 to about 500 nm or about 30 to about 150 nm in size. The CIS comprising nanoparticles can be formed with a narrow distribution in size. The CIS comprising nanoparticles can form an interconnecting network, particularly when the nanoparticles are small, for example 10 to 20 nm on average. The size of the nanoparticles and the interconnectivity depends upon the synthesis conditions, where the precursor ratio plays an important role. The method to prepare the CIS comprising nanoparticles is carried out without a surfactant or other binding agent, such that removal of such agents does not complicate the conversion of a deposited precursor layer to an absorber layer during the fabrication of a photovoltaic device and not restrict the substrate for the device to those unaffected by high temperatures.

In an embodiment of the invention, the CIS comprising nanoparticles are used to form an ink that is used for the deposition of the CIS comprising absorber layer precursor in a novel method for formation of a photovoltaic device. The ink is formed by blending a solvent with CIS comprising nanoparticles, which, as needed, can be CIS comprising nanoparticles of different sizes or composition such that the overall composition of the ink produces a final CIS comprising absorber layer that exhibits a desired stoichiometry and a uniform composition. The solvent can be, for example, alcohols, sulfoxides, or any other solvent or combination of solvents selected to have an appropriate viscosity, volatility and affinity for the CIS comprising nanoparticles.

Other embodiments of the invention are directed to a method of depositing a CIS absorber layer comprising spray coating, drop casting, screen printing, or inkjet printing the ink of the appropriate viscosity to form a layer of the absorber layer precursor and its subsequently annealing under a selenium atmosphere to yield the CIS comprising absorber layer. Annealing is carried out at temperature less than about 380° C., for example less than about 350° C., less than about 300° C., or less than about 260° C. Other embodiments of the invention are directed to a photovoltaic device comprising a CIS comprising absorber layer and a method to form a photovoltaic device. The absorber layer can be formed on substrates that require relatively low temperature processing, for example, polymeric substrates.

The CIS comprising nanoparticles are prepared by combining a copper salt with an indium salt and selenium in solution. The copper salt can be CuCl, CuBr, CuI, CuCl₂, CuBr₂, CuI₂, Cu₂Cl₂, Cu₃Cl₃, Cu₂Br₂, Cu₃Br₃, Cu₂I₂, Cu₃I₃, any combination thereof, or their equivalent, for example the copper salt can be copper acetate. The indium salt can be InCl, InCl₂, InCl₃, InI, InI₂, InI₃, InBr, InBr₂, InBr₃, any combination thereof or their equivalent, for example, the indium salt can be indium acetate. The salts are dissolved in an alcohol, such as methanol, ethanol, C3 to C8 alcohol, or combination of alcohols. The alcohol solution or solutions are combined under an inert atmosphere, for example nitrogen or argon, with a selenium solution that is formed by dissolving selenium powder in an amine solvent, such as isopropyl amine, isobutyl amine, butyl amine, methylamine, ethylamine, ethylenediamine, other C3 to C8 amine, C3 to C8 diamine, or any combination thereof. The combined solution is heated at a relatively low temperature, for example below about 150° C., below about 120° C., or below 90° C., which results in the formation of the CIS comprising nanoparticles of a desired average size after a sufficient period of time. For example, the combined solution can be refluxed at a temperature that depends on the alcohols and amines employed as solvents but at a temperature below 120° C. The combined solution is refluxed for a period of hours, for example about 1 hour to about 24 hours as needed or desired for the formation of CIS comprising nanoparticles having a desired size. The proportions of the copper salt, indium salt and selenium can be varied to achieve a desired stoichiometry of the CIS comprising nanoparticles. The CIS comprising nanoparticles can be isolated as a precipitate and washing with methanol.

Typically, CIS comprising nanoparticle formation is carried out with a stoichiometric excess of copper salt and selenium such that the desired CIS comprising nanoparticles include a secondary phase, where the secondary phase comprises CuSe₂, CuSe, or Cu₃Se₂. The secondary phase promotes liquid assisted growth during CIS comprising absorber layer formation to enhance the grain size of the CIS in the ultimate CIS comprising absorber layer. The CIS phase of the CIS comprising nanoparticles can be in the cubic (spharelite) structure or the tetragonal (chalcopyrite) structure. When the secondary phase is CuSe, the CuSe can exist in the any one of α-CuSe, β-CuSe, γ-CuSe. In embodiments of the invention, the CIS phase of the CIS comprising nanoparticles can have indium replaced, up to 100%, with one or more of Ga, Al, Zn, and Sn, in the group III cation sublattice, copper, can be replaced with Ag and/or Au in the cation sublattice, or the CIS nanoparticles can be part of a solid solution with one or more of Ga, Al, Zn, Sn, Au and Ag. In embodiments of the invention, the CIS phase of the CIS comprising nanoparticles can have a portion of the Se, up to 100%, replaced with sulfur or tellurium in the anion sublattice to form, for example CuInS₂ or the CIS nanoparticles can be part of a solid solution with sulfur, for example CuIn(SₓSe₁₋ₓ)₂. In embodiments of the invention, the CIS phase of the CIS comprising nanoparticles can have any portion of indium in the CIS phase replaced with Al, Ga, Zn, or Sn, or Cu replaced with Au or Ag in the cation sub-lattice or the CIS comprising nanoparticles can be in the faun of a solid solution with one or more of Al, Zn, Ag, Sn, Ga and Ag while simultaneously the anion sub-lattice can have a portion of the Se replaced with sulfur or tellurium or where the solid solution further comprises sulfur or tellurium.

Inks can be prepared from the isolated CIS comprising nanoparticles, where, as desired, different sized CIS comprising nanoparticles and CIS comprising nanoparticles with different stoichiometry can be combined. For example, copper-rich CuInSe₂ comprising nanoparticle with indium-rich CuInSe₂ comprising nanoparticle can be mixed together in inks used to form stoichiometric CuInSe₂ CIS comprising absorber layers for bottom cells. For example, copper-rich CuInS₂ comprising nanoparticle with indium-rich CuInS₂ comprising nanoparticle can be mixed together in inks used to form stoichiometric CuInS₂ CIS comprising absorber layers for multi junction devices.

The inks can be deposited on a device including an inflexible substrate such as glass or on a flexible substrate such as a metal, for example stainless steel, or a polymer, for example a polyimide. The ink can be deposited directly onto a MoSe₂ layer, which promotes good ohmic contact between a molybdenum electrode on the substrate and the resulting CIS comprising absorber layer formed after solvent removal to form a precursor layer that is annealed in a Se atmosphere. Deposition of other layers, for example those shown if FIG. 1, can be carried out by any method that is known by those skilled in the art and can be of any material that is consistent with a photovoltaic device having a CIS active layer that is known by those skilled in the art.

### Methods and Materials

In an exemplary embodiment, 0.01 gmol of anhydrous cuprous chloride, CuCl in 20 ml of ethyl alcohol and 0.01 mol of anhydrous InCl₃ dissolved in 25 ml n-propyl alcohol with agitation for 2 hours. This alcohol solution was combined with 0.02 gmol Se powder in 40 ml of ethylenediamine under an inert atmosphere to form a homogeneous solution. The Cu—In—Se solution was refluxed at ˜110° C. under an inert atmosphere for 5 hours during which nucleation and growth of the CIS comprising nanoparticles occurred. The resulting precipitates were washed with methanol and vacuum-dried to obtain pure CIS comprising nanoparticles with secondary phases of CuSe₂ and/or CuSe.

In like fashion, CIS comprising nanoparticles were synthesized the above low-temperature solution based method, where the molar ratio of precursors Cu(OC(O)CH₃)₂ or CuCI:InCl₃ or In(OC(O)CH₃)₃:Se were varied from 1:1:1 to 2:1:2. Anhydrous reagents were used and nucleation and growth temperatures were maintained below 120° C. for periods up to 20 hours. The resulting CIS comprising nanoparticles precipitated, the precipitate were washed with methanol to remove impurities, and the washed precipitate was vacuum dried at about 80° C. to yield the CIS comprising nanoparticles. The CIS comprising nanostructure preparation developed in this study was very reproducible. The structural and optoelectronic properties of the CuInSe₂ comprising nanoparticles were characterized by TEM, HR-TEM, EDX, XRD, PL, SAED and Raman spectra.

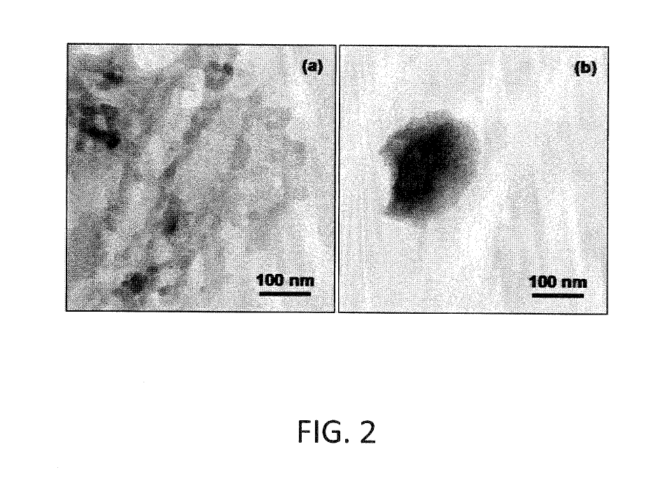

In one series of experiments the above procedure was carried out with a Cu:In:Se molar ratio of 2:1:2 using identical solvents, temperatures and times but where the copper precursor varied. FIG. 2 shows the TEM images of the resulting CIS comprising nanoparticles. As shown in FIG. 2b, copper acetate and InCl₃ as precursors resulted in monodispersed CIS comprising nanoparticles of about 150 nm. In contrast, CIS comprising nanoparticles prepared from CuCl and InCl₃, as shown in FIG. 2a, display an interconnected network of CIS comprising nanoparticles of about 10 to 20 nm. XRD patterns indicated that the structure of the CIS comprising nanoparticles from cupric acetate had tetragonal crystals and some orthorhombic CuSe₂ secondary phase whereas the corresponding CIS comprising nanoparticles from cuprous chloride displayed a cubic phase and some orthorhombic CuSe₂ secondary phase. Room temperature micro-Raman spectra of both CIS comprising nanostructures grown by using different Cu-precursors exhibit the two major characteristic peaks of CuInSe₂ and some binary peaks from CuₓSe_{y} and InₓSe_{y}. Raman and PL spectra are consistent with the superior optoelectronic properties of tetragonal CIS for the CIS comprising nanoparticles made from cupric acetate, in good agreement with the TEM and XRD results.

In another series of experiments tabulated below in Table 1, CIS comprising nanoparticles were prepared in equivalent solutions at equivalent times and temperatures but with various precursors and molar ratios of the precursors. Phase transformation studies were performed on this series of CIS comprising nanoparticles using a PANalytical X'Pert system and Scintag-HTXRD with and without an overpressure of selenium. The PANalytical-HTXRD system is composed of a PANalytical X'Pert Pro MPD θ/θ X-ray diffractometer equipped with an Anton Paar XRK-900 furnace and an X'Celerator solid state detector. A surrounding heater is used for heating the samples. The Scintag-HTXRD consists of a Scintag PAD X vertical θ/θ goniometer, a Buehler HDK 2.3 furnace, and an mBraun linear position sensitive detector (LPSD). In conventional X-ray diffraction, point scanning detectors are used to collect data that perform the scanning step-by-step from lower to higher angles, where as the LPSD collects the XRD data simultaneously over a 10° 2θ window, dramatically shortening the data collection time. This allows for in situ time-resolved studies of phase transformations, crystallization, and grain growth. Temperature is measured by type-S thermocouple welded onto the bottom of a Pt/Rh strip heater and gives feedback to the temperature controller. Samples are mounted on the heater strip using carbon or silver paint to improve the thermal contact between the precursor and heater strip. The sample temperature is calibrated by measuring the lattice expansion of a silver powder sample dispersed on an identical substrate and comparing the results with that suggested by the literature. The PANalytical-HTXRD system is composed of a PANalytical X'Pert Pro MPD θ/θ X-ray diffractometer equipped with an Anton Paar XRK-900 furnace and an X'Celerator solid state detector. A surrounding heater is used in a PANalytical-HTXRD to heat the samples. The temperature difference between the furnace and the sample differs by ±1° C. Both HTXRD furnaces were purged by flowing N₂. Most of the selenization experiments were carried out in the PANalytical-HTXRD with a graphite dome used to prevent the loss of selenium due to volatilization.

TABLE 1
Nanoparticle synthesis for CIS absorber formation

| | | | Molar |
|---|---|---|---|
| | | | ratio |
| Sample | Precursor | Solvent | Cu:In:Se |
| UF5 | CuCl, InCl₃, Se | ethanol, propanol, ethylenediamine | 1:1:1 |
| UF5′ | Cu(OAc)₂, | ethanol, propanol, ethylenediamine | 1:1:1 |
| | In(OAc)₃, Se | | |
| UF9 | CuCl, InCl₃, Se | ethanol, propanol, ethylenediamine | 2:1:2 |

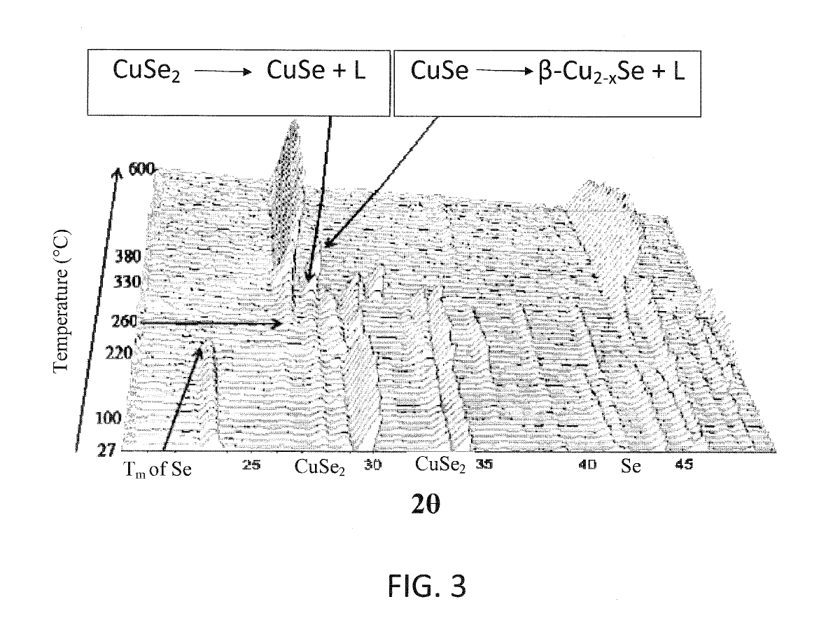

The atomic composition of UF5 was determined by inductively coupled plasma optical emission spectroscopy (ICP-OES). Results showed that the samples was copper-rich and the ratio of Cu/In was 5.016. The room temperature scan showed CIS (cubic), CuSe₂ (orthorhombic) and excess selenium consistent with the ICP results. Low resolution TEM was performed and the particle size was estimated to be 50 nm. Temperature ramp studies with the high temperature XRD system were performed as indicated above, where the temperature of the sample was increased rapidly in 10° C. increments with an XRD pattern determined after each step where the scan time was about one minute. The phase evolution for UF5 is shown in FIG. 3. At around 250° C. the cubic phase of CIS transforms to the desired tetragonal (chalcopyrite) phase. As can be seen in FIG. 3, the copper diselenide (CuSe₂) undergoes a peritectic reaction at 604.3 K (331° C.) to yield solid copper monoselenide (CuSe) and a Se-rich liquid phase. A further increase in temperature results in a second peritectic reaction at 381.8° C. where copper monoselenide transforms to solid β-Cu₂₋ₓSe and a slightly less Se-rich liquid phase. Removal of the metallic β-Cu₂₋ₓSe phase is metallic is necessary and can be performed by wet etching using potassium cyanide (KCN) or further reaction with In. This is consistent with grain growth of CIS that is assisted by the formation of a liquid phase. Therefore, CIS grain growth under these conditions occurs at a relatively low temperature, allowing a reduction of heating and cooling periods in a deposition process and permitting the use of some flexible substrates.

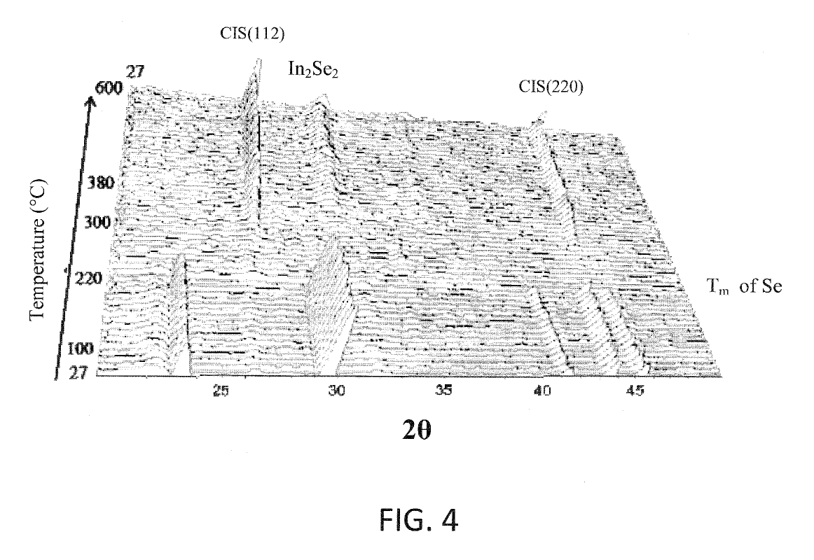

The atomic composition of UF5′ was determined by inductively coupled plasma optical emission spectroscopy (ICP-OES). Results indicated that the resulting CIS comprising nanoparticles were copper-poor with a Cu/In ratio of 0.326. The Se to metal ratio was 4.5. Room temperature scan identified CIS (cubic), CuSe (hexagonal), InSe (hexagonal), In₂Se₃ and excess selenium in the UF5′ samples. CuSe and InSe appear to be amorphous as XRD pattern displayed broad features. Low resolution TEM revealed a core-shell type of structure. A temperature ramp XRD plot is shown in FIG. 4. The elemental selenium peaks disappeared at ˜220° C., which is consistent with the melting of selenium. The CIS transformed from a cubic phase of to tetragonal phase at ˜250° C. and grain growth of CIS (112) initiated around 300° C. with growth completed at ˜380° C. where there is no change in the intensity of the peaks due to formation of In₂Se₃. The formation of In₂Se₃ indicates that the nanoparticle is indium and selenium-rich. Although the formation of an ordered vacancy compound (OVC) under indium rich condition has been reported, this phase was not apparent in the temperature ramp, perhaps because excess indium reacts with the excess selenium to form In₂Se₃.

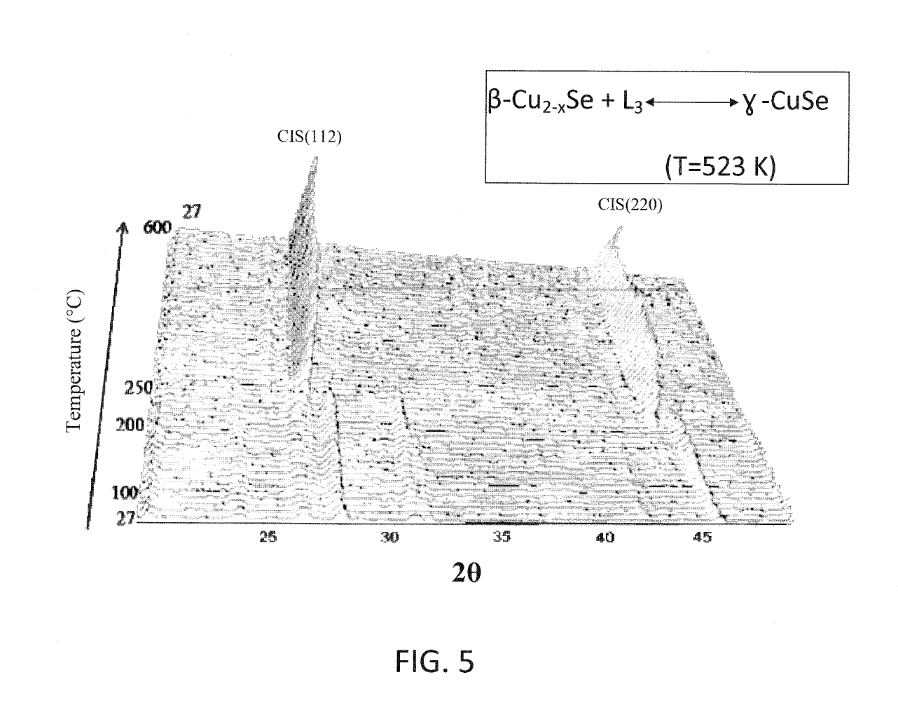

The atomic composition of UF9 was determined by inductively coupled plasma optical emission spectroscopy (ICP-OES). Results indicated that the samples were copper-rich and the Cu/In ratio was 1.3. Room temperature scan displayed CIS (cubic), CuSe (hexagonal) InSe (hexagonal) that are consistent with ICP results. The Se to metal ratio was 0.53. CuSe and InSe phases appear to be amorphous with broad XRD patterns. Low resolution TEM revealed nanorod-like structure with a 100 nm length and a 20 nm diameter. A Temperature ramp XRD plot is shown in FIG. 5, where transformation of cubic phase CIS to tetragonal phase at ˜250° C. with simultaneous CuSe and InSe peak disappearance. Complete reaction is indicated at ˜280° C. by no change in the intensity of the peak due to CIS (112). At ˜300° C., CuIn (134) compound formation begins and subsequently disappears at ˜340° C. Above ˜340° C., the CuIn compound reacts with selenium supplied as an overpressure to form In₂Se₃ (110) and CuSe (102).

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

1. A CIS comprising nanoparticle comprising:
Cu, where optionally Cu includes some Au, Ag or both;
In, Al, Zn, Sn, Ga, or any combination thereof; and
Se, S, Te or any combination thereof, wherein the nanoparticle further comprises a secondary phase that comprises a compound that decomposes to a liquid, is free of a surfactant or binding agent.

2. The CIS comprising nanoparticle of claim 1, wherein the CIS comprising nanoparticle comprises Cu, In, and Se with a secondary phase comprising CuSe, CuSe₂, Cu₃Se₂, or any combination thereof.

3. The CIS comprising nanoparticle of claim 2, wherein the CuSe is α-CuSe, β-CuSe, or γ-CuSe.

4. The CIS comprising nanoparticle of claim 1, wherein the CIS comprising nanoparticle has a cubic (spharelite) or tetragonal (chalcopyrite) CIS crystal lattice.

5. The CIS comprising nanoparticle of claim 4, wherein the CIS crystal lattice comprises Cu, In, and Se where a portion of its In is substituted with Al, Zn, Sn, Ga, or any combination thereof, and/or Cu is substituted with Au, Ag, or any combination thereof in the cation lattice.

6. The CIS comprising nanoparticle of claim 4, wherein the CIS crystal lattice comprises Cu, In, and Se where a portion of its anion lattice is substituted with S and/or Te.

7. The CIS comprising nanoparticle of claim 4, wherein the CIS crystal lattice forms a solid solution comprising Al, Zn, Au, Sn, Ga, Ag or any combination thereof.

8. The CIS comprising nanoparticle of claim 4, wherein the CIS crystal lattice forms a solid solution comprising sulfur or tellurium.

9. (canceled)

10. (canceled)

11. A method to prepare the CIS comprising nanoparticle of claim 1 comprising:
providing a copper halide or its equivalent in a first solution;
providing an indium halide or its equivalent in a second solution;
providing selenium or sulfur in a third solution;
combining the first solution with the second solution and the third solution;
heating the combined solution to a temperature up to 150° C. to form a precipitate; and
optionally, washing the precipitated CIS comprising nanoparticles, wherein no surfactant or binding agent is included in any solution.

12. The method of claim 11, wherein the copper halide is CuCl, CuBr, CuI, CuCl₂, CuBr₂, CuI₂, Cu₂Cl₂, Cu₃Cl₃, Cu₂Br₂, Cu₃Br₃, Cu₂I₂, Cu₃₁₃, CuOC(O)CH₃, Cu(OC(O)CH₃)₂, Cu₂(OC(O)CH₃)₂, Cu3(OC(O)CH₃)₃, or any combination thereof.

13. The method of claim 11, wherein the indium halide is InCl, InCl₂, InCl₃, InI, InI₂, InI₃, InBr, InBr₂, InBr₃, InOC(O)CH₃, In(OC(O)CH₃)₂, In(OC(O)CH₃)₃, or any combination thereof.

14. The method of claim 11, wherein the solvent for the first solution and second solution independently comprise methanol, ethanol, C3 to C8 alcohol, or any combination thereof.

15. The method of claim 11, wherein the solvent for the third solution comprises isopropyl amine, isobutyl amine, butyl amine, methylamine, ethylamine, ethylenediamine, other C3 to C8 amine, C3 to C8 diamine, or any combination thereof.

16. The method of claim 11, wherein heating comprises refluxing in the solvents of the combined solutions.

17. The method of claim 11, wherein washing is performed with methanol or any volatile alcohol.

18. The method of claim 11, further comprising drying the CIS comprising nanoparticles.

19. (canceled)

20. An ink comprising the CIS comprising nanoparticles according to claim 1 and one or more solvent.

21. The ink of claim 20, wherein the solvent is an alcohol or a sulfoxide.

22. (canceled)

23. A method of preparing a CIS comprising absorber layer comprising:
forming a layer of ink according to claim 20 on a surface;
removing the solvent from the ink to form a precursor layer; and
annealing the precursor layer under an overgas of selenium or sulfur to form the CIS comprising absorber layer.

24. The method of claim 23, wherein forming is spray coating, drop casting, screen printing, or inkjet printing.

25. (canceled)

26. (canceled)

27. A CIS comprising absorber layer, comprising CuInSe₂ with a microstructure comprising lamellar grains.

28. The A CIS comprising absorber layer of claim 27, wherein the microstructure further comprises columnar grains.

29. A photovoltaic device comprising the CIS comprising absorber layer of claim 27.

30. The photovoltaic device of claim 29, further comprising a metallic or polymeric substrate.

31. (canceled)
